(19) United States
(12) Patent Application Publication
(10) Pub. No.: US 2025/0309052 A1
(43) Pub. Date: Oct. 2, 2025

(54) EMBEDDED JET COOLING FOR SEMICONDUCTOR PRODUCTS

(71) Applicant: MELLANOX TECHNOLOGIES, LTD., Yokneam (IL)

(72) Inventors: Ran Hasson Ruso, Pardes Hanna-Karkur (IL); Elad Mentovich, Tel Aviv (IL)

(21) Appl. No.: 18/618,635

(22) Filed: Mar. 27, 2024

(51) Int. Cl. H01L 23/473; H01L 23/427

(52) U.S. Cl. CPC H01L 23/4735; H01L 23/427

(57) ABSTRACT

Systems and methods herein are for a semiconductor product having at least one channel and at least one nozzle formed on or within a surface thereof, where the at least one channel can allow flow of a liquid therethrough, where the at least one nozzle can allow ejection of the liquid to the surface or to an area above the surface, where an enclosure retains the liquid, to provide at least part of a cooling of the semiconductor product having heat absorbed to the liquid from device activity in the semiconductor product.

### TECHNICAL FIELD

At least one embodiment pertains to a channel-based cooling system for semiconductor products.

### BACKGROUND

Developments in semiconductor products, including in circuit boards and semiconductor chips, have contributed to increased heat generated from such semiconductor products. For example, silicon circuits of the semiconductor product perform compute, storage and other operations, reflecting part of device activity, which may include intensive or other operations that may all contribute to increased heat generation. The heat can have an impact on utilization and performance of the semiconductor product. For example, the heat can adversely impact compute potential of current and next-generation semiconductor products, including of next-generator silicon-based processors. Transfer of heat to heatsinks or cold plates allow heat to be removed from a semiconductor product using air or liquid. To move heat to a heatsink or cold plate, different thermal interface materials (TIMs) may be used. This allows vertical heat transfer from a semiconductor product to the heatsink or cold plate. Further, this may also allow horizontal heat spreading that moves heat across a semiconductor product. In another example, spot cooling of a semiconductor product allows heat to be moved away using a transfer via liquid. However, cooling in semiconductor products may be still considered to have a latency with respect to heat removal. For example, cooling may be provided by heat spread via thermal conductivity to a heat sink, cold plate, or vapor chamber, but may involve a latency to ramp up cooling as heat increases, for instance.

### BRIEF DESCRIPTION OF DRAWINGS

FIG. 1 is an illustrative plan view of a semiconductor product subject to embedded jet cooling using channels and a nozzle defined thereon or therein, in at least one embodiment;

FIG. 2A is an illustration of an application of embedded jet cooling using channels and at least one nozzle of a semiconductor product, in at least one embodiment;

FIG. 2B is a side view illustration of channels and at least one nozzle of a semiconductor product, in at least one embodiment;

FIG. 3 illustrates aspects of a hot area mapping and liquid cooling loops in embedded jet cooling using channels and at least one nozzle of a semiconductor product, in at least one embodiment;

FIG. 4 illustrates computer and processor aspects of embedded jet cooling using channels and at least one nozzle of a semiconductor product, according to at least one embodiment;

FIG. 5 illustrates a process flow for embedded jet cooling using channels and at least one nozzle of a semiconductor product, according to at least one embodiment;

FIG. 6 illustrates yet another process flow for embedded jet cooling using channels and at least one nozzle of a semiconductor product, according to at least one embodiment; and

FIG. 7 illustrates a further process flow for operating a semiconductor product having embedded jet cooling using channels and at least one nozzle of the semiconductor product, according to at least one embodiment.

### DETAILED DESCRIPTION

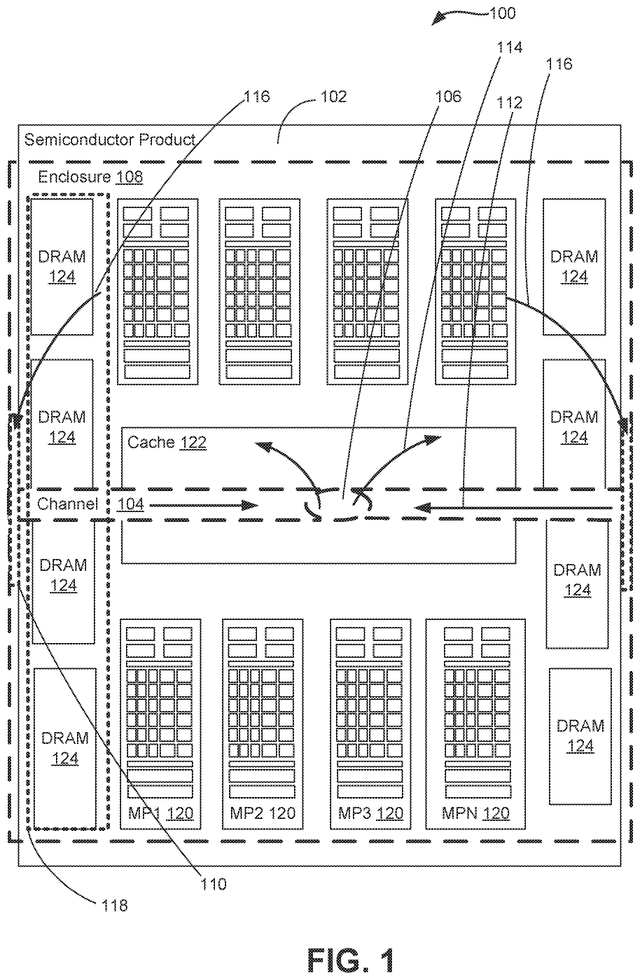

FIG. 1 is an illustrative plan view of a semiconductor product 100 subject to embedded jet cooling using channels and a nozzle defined thereon or therein, in at least one embodiment. In at least one embodiment, the embedded jet cooling herein utilizes liquid that enters hot areas of a semiconductor product through channels embedded to a top surface of a silicon layer of the semiconductor product. Therefore, the channels and the nozzle maybe on top or just below the surface of the semiconductor product. The liquid is enabled to be ejected as a high-speed jet of a liquid through one or more nozzles associated with the channels. This provides a channel-based cooling mechanism that allows near instant removal of heat from a silicon substrate.

In at least one embodiment, the ejection of liquid allows for instant removal of heat from the semiconductor product that may be in the format of a semiconductor chip, die, or other formats that may include packaged formats. In one example, the top surface of the silicone layer may be provided with channels (also referred to herein as micro-channels), which allow for liquid that may be a heat-carrier liquid to reach above active or hot areas of the semiconductor product. Further, heat generated from device activity, such as operation of a semiconductor product, may cause vaporization of the liquid with the ejection occurring within an enclosure around the semiconductor product. The vaporization of the liquid is used beneficially for the cooling herein. For example, the vaporization can cause the ejection of the liquid as droplets extend out of the one or more nozzles of the channels. Further, the vaporization may cause vacuum within the channel to pull more of the liquid to the one or more nozzles.

As such, in at least one embodiment, the silicon embedded jet cooling herein is a self-regulating cooling approach to address hot areas, where, based in part on the heat of a hot area, a determined amount of the liquid is caused to be ejected and may cause to occur at a determined frequency. Therefore, there may be a relationship established between the heat and one or more of an amount, an ejection rate, or a frequency of ejection. Therefore, it is possible to control the heat or to provide cooling in a predetermined manner based in part on one or more of an amount, an ejection rate, or a frequency of ejection of a liquid used to cool the hot area.

In one example, the liquid is enabled to move in the silicon's channels in either a closed loop (also referred to herein as a passive loop) or an open loop (also referred to herein as an active loop). In at least the open loop, a pump may be used to cause the movement. However, the action of the heat causing vacuum may be sufficient to cause the movement for at least part of the open loop. Further, the liquid is vaporized in the enclosure near or around the one or more nozzles. As such, the vapor may be caused to eject or shoot outward (and upward) from the nozzles. The vapor may be caused to condense on a surface of the enclosure. The liquid, once condensed, is returned via a collection feature and is allowed to feed the channels to provide the closed loop.

In the open loop, at least part of the liquid may be caused to be exchanged in a heat exchanger to cool the liquid. However, it is appreciated that there is a determined amount of heat to be within the liquid to enable the vaporization. Therefore, the channels and the part of the liquid removed may be based in part on the requirement to ensure that vaporization occurs for the liquid. In at least one embodiment, it is also the case that the liquid is used in the liquid form to cause the cooling without vaporization or with only vaporization in part. The determined amount of heat may be based in part on a specification determined for the liquid to have a vaporization temperature but may be also based in part on a specification that is suitable to the semiconductor product or a part thereof. In at least one embodiment, the channels herein can allow preheating of the liquid to achieve the determined specification for one or more of the liquid or the semiconductor product or part thereof, before the liquid arrives at the nozzle for vaporization. In at least one embodiment, the passive and the active loops are able to provide support for any alignment or orientation for the semiconductor product. For example. side mounted chips, face-down chips, or provision of condensation areas within an enclosure may be supported by the passive loop, whereas semiconductor products requiring vapor suction may be supported by the active loop.

FIG. 1, therefore, illustrates a semiconductor product 100 capable of self-regulated and channel-based cooling. For example, embedded jet cooling is enabled within an active or passive loop using channels 104 and using at least one nozzle or notch 106 defined within a surface 102 of the semiconductor product 100. The semiconductor product 100 may include the at least one channel 104 that may extend from one or more sides (providing one or more collection features 110) of an enclosure 108 to the nozzle or notch 106. Further, although illustrated with a dome-like shape, the enclosure 108 may include a suitable shape to allow at least gravity movement of condensate return or liquid return of the liquid. Particularly, a channel 104 is provided from a collection feature 110 to the at least one nozzle or notch 106. While the channel and the nozzle may be formed into a surface, such as a silicon surface, a packaged surface, or a circuit surface of the semiconductor product, the enclosure may be a metallic feature formed before or after packaging is applied to the semiconductor product 100. Therefore, the semiconductor product 100 may be an exposed silicon surface or may be a packaged or circuit surface, all subject to the embedded jet cooling herein.

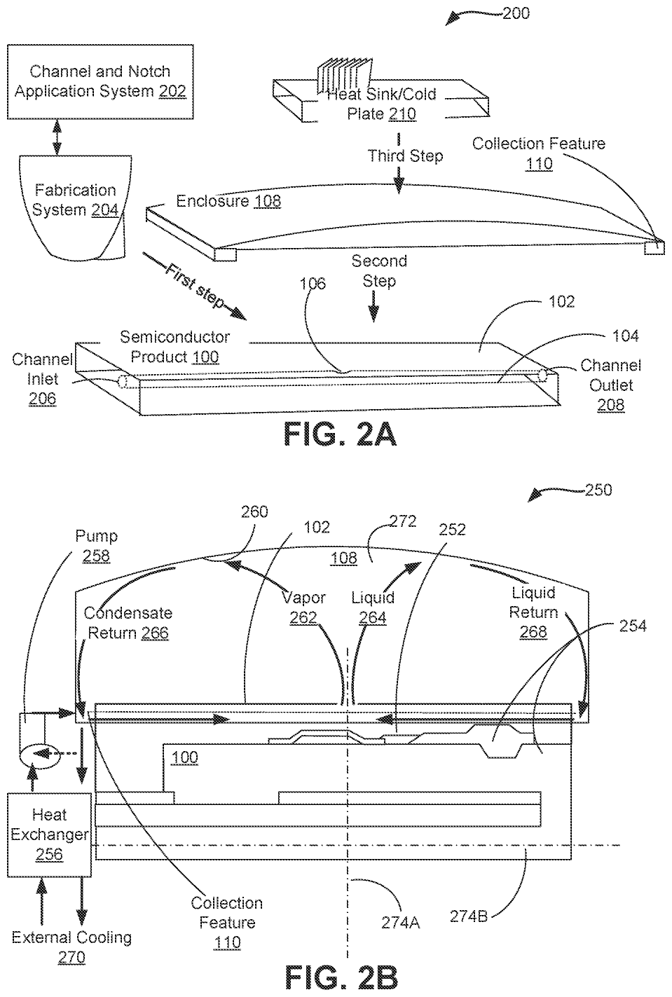

In at least one embodiment, the at least one channel 104 allows liquid to flow or move 112 therethrough to partly cool the semiconductor product 100 in a first action and to eject 114 from the at least one nozzle or notch 106 to a surface 102 or an area above the surface of the semiconductor product (such as illustrated in FIGS. 2A and 2B herein) in a second action. These actions may be based in part on retained heat in the liquid from the semiconductor product as device activity occurs. These actions may provide different mechanisms of cooling to the semiconductor product 100. For example, the first action provides first cooling to remove part of the heat in the semiconductor from the device activity, by a form of absorption cooling of the heat, in a preheating step for the liquid. The second action provides further cooling for the heat by a form of evaporative cooling, for instance, using vapor or liquid form of the liquid ejected from the nozzle or notch 106. The heat removed from the second action may be higher than the heat removed from the first action, in at least one embodiment. The liquid that is ejected 114 from the nozzle is either in the liquid form or in vaporized form. The liquid form or any condensed form of the vaporized liquid may be retained within an enclosure to support cooling of the semiconductor product. For example, the liquid may bead off walls of the enclosure and returning 116 to collection features 110 provided in different parts of a bottom part of the enclosure 108. This allows the liquid in the semiconductor product to be reused or to undergo a heat exchange outside the semiconductor product 100.

In one example, a channel with a notch may be formed by one or more of micro-milling, etching, deposition, lithography, embossing processes, and laser ablation processing. This may be performed, as detailed in at least FIG. 2A, directly to a silicon, packaging, or circuit top or bottom surface of a semiconductor product 100. The liquid may be pumped, as detailed in at least FIG. 2A, or caused to flow by a temperature difference in the semiconductor product 100. There may be one or more liquid inlets and outlets associated with enclosure 108 and with a heat exchanger for the reuse of the liquid for the cooling purpose. The embedded jet cooling herein is able to use channels having a notch or nozzle directly formed on the surface of the semiconductor product to cool the semiconductor product based on instant heat changes as a result of a byproduct of a device activity occurring in the semiconductor product, which can address heat removal latency otherwise experienced by such semiconductor products 100.

While illustrated as an integrated circuit, such as a graphics processing unit (GPU), a central processing unit (CPU), a data processing unit (DPU), or any other processing unit. In at least one embodiment, the semiconductor product 100 may be a circuit board, such as a printed circuit board (PCB). Further, as to at least the processing units, a form factor of the semiconductor product 100 that is a GPU, a CPU, or a DPU, may be a wafer form factor, a die form factor, a packaged chip form factor, or a circuit board form factor.

Further, in FIG. 1, the semiconductor product 100 may include hot areas 118 that may be execution units, memory areas, and other such areas subject to device activity at different times during operation or use of the semiconductor product 100. Therefore, the illustrated hot area 118 is only one example area. The hot area 118 may be defined, in part, by components therein. However, in at least one embodiment, the hot areas may be defined generally on the surface 102 of the semiconductor product 100. For example, as illustrated, hot area 118 may be used to create part of the channels to allow preheating of the liquid to achieve the determined specification for one or more of the liquid or the semiconductor product 100 or part thereof, before the liquid arrives at the nozzle for vaporization. FIG. 1 also illustrates that a semiconductor product 100 may include other components, including a cache 122, such as a unified L2 cache, multiple dynamic random access memory (DRAM) 124, one or more memory controllers, and L1 caches, which may be other hot areas 118 subject to preheating or generally subject to cooling by the embedded jet cooling herein.

In at least one embodiment, a hot area 118 may be predetermined hot areas or areas capable of generating more heat than other areas of the surface 102. The hot areas 118 may generate heat as a result of an underlying one of the components, such as the cores of a multiprocessor (MP) 120. There may be cooler areas, relative to the hot areas 118, which may be used to plan the layout of the channels and the at least one nozzle on the surface 102 of the semiconductor product 100. In at least one embodiment, it is possible to provide multiple enclosures 108 than illustrated. For example, the enclosure 108 may be specific to one or more components 120, 122, 124.

In at least one embodiment, it is possible to perform an application of embedded jet cooling using channels and at least one nozzle on a semiconductor product that is in a die format, a wafer format (which may be followed by cutting), or in a packaged semiconductor format of any type of package, including a stacked-die package and a multi-chip package (MCP). The application herein is to provide the embedded jet cooling using a nozzle or notch in a channel, where the nozzle or notch is at about a nine micron or smaller scale, in any of these semiconductor products. Further, prior to application, the channel and the notch herein is provided by a microchannel fabrication that may include one or more of micro-milling, etching, deposition, lithography, embossing processes, and laser ablation processing.

The embedded jet cooling herein is able to provide a semiconductor product 100 with uniform and instant cooling. For example, heat generation may be because of changes in computing or device activity and according to functions of different components within the semiconductor product. A change, in one example, may be based in part on usage of such components in a computing environment. For example, memory usage may cause the memory components to generate more heat relative to other components on the surface of a semiconductor product, whereas processing usage may cause the processing components or cores to generate more heat relative to other components, including the memory components on the surface of a semiconductor product.

In at least one embodiment, the liquid used in embedded jet cooling herein may be in a chemical family of a monomer of polymers based on certain solvents, as may be the solvent themselves. For example, the chemical family may pertain to one or more of 2-Methylpentane, 3-Methylpentane, Methanol (methyl alcohol, wood alcohol), Alcohol-methyl (methyl alcohol, wood alcohol, wood naphtha or wood spirits), CH₃OH, Diisopropyl ether, Methylcyclopentane, Butanal, Carbon Tetrachloride (Tetrachloroethane) CCl₄, Acrylonitrile, Ethyl acetate (CH₃COOC₂H₃), Ethanol, Alcohol-ethyl (grain, ethanol) C₂H₅OH, 2,2-Dimethylpentane, 2-Butanon, Isopropyl Alcohol, Cyclohexane, Acetonitrile, 2-Propanol, Alcohol-allyl, Alcohol-propyl, n-Heptane, Isooctane, Naphtha, Water, sea water, Methylcyclohexane, 1,4-Dioxane, Alcohol-Isobutyl, saturated brine, Diisobutyl, Alcohol-butyl-n, 1-Butanol, Paraldehyde, p-Xylene, or m-Xylene.

FIG. 2A is an illustration of an application 200 of embedded jet cooling using channels and at least one nozzle of a semiconductor product, in at least one embodiment. The application 200 may include a channel and notch application system 202 to control the application 200 of the channel 104 and the nozzle or notch 106 to the semiconductor product 100. Although illustrated in the singular, it is possible that the application 200 occurs to provide multiple channels and nozzles. This is followed up by application of the enclosure 108. The enclosure 108 may be affixed by any fixed or removable process to associate a metal cap or casing to the semiconductor product 100.

In at least one embodiment, the semiconductor product 100 illustrated is in a die form factor, a wafer form factor, package form factor, or circuit form factor is illustrated in a perspective view. The channel and notch application system 202 can control the application 200 of the channel 104 and the nozzle or notch 106 to the semiconductor product 100 using the fabrication system 204 that may be based on part on one or more of a micro-milling system, an etching system, a deposition system, a lithography system, an embossing system, or a laser ablation system. In one example, a mask of multiple channels and of multiple nozzles may be provided to the surface 102 of the semiconductor product 100. Further, the surface 102 may include one or more sides of the semiconductor product to allow association of the channel 104 with the collection feature 110 of the enclosure 108. The channel 104 and the nozzle 106 may be formed using such a fabrication system 204 that may be otherwise used to provide one or more of the features 254 (in FIG. 2B) otherwise used for device activity.

FIG. 2B is a side view illustration 250 of channels and at least one nozzle of a semiconductor product, in at least one embodiment. The semiconductor product 100 may include one or more features 254 such as, interconnects, vias, and dielectric layers. The features 254 may include non-uniform surfaces on the semiconductor product 100. Further, the features 254 may overlay transistors or other structures that belong to a compute circuit or a memory circuit 120-124 of the semiconductor product 100. As such, these may be hot areas 118, based in part on the device activity associated with these features 254 of the semiconductor product 100.

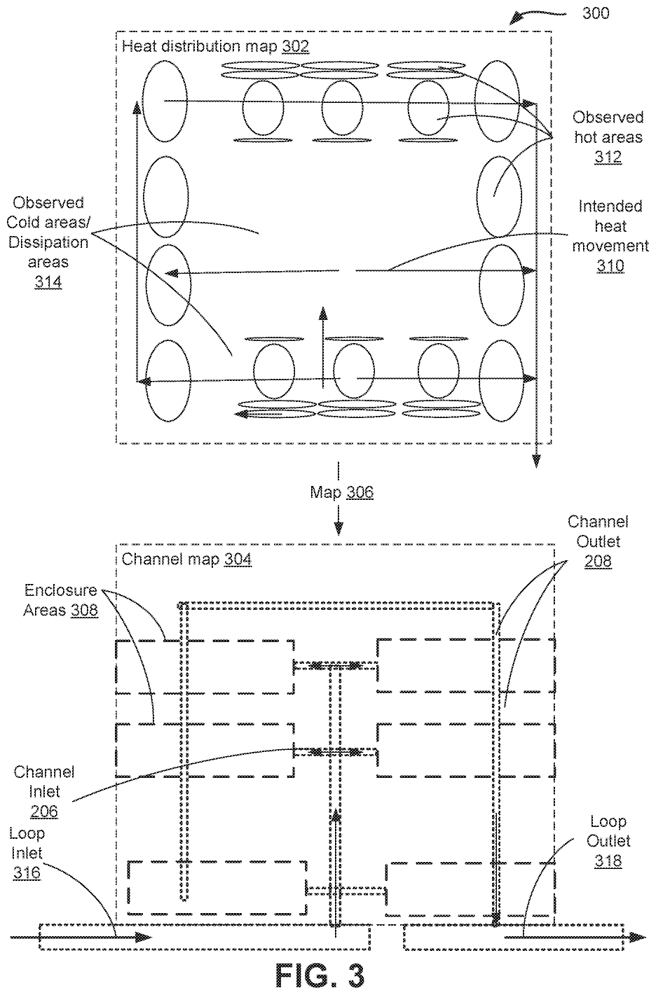

As illustrated in FIGS. 2A and 2B, the semiconductor product 100 includes at least one channel 104 and at least one nozzle formed on a surface 102 thereof, in a first step of preparing the embedded jet cooling herein. The channel 104 is associated with a channel inlet 206 and a channel outlet 208. Further, the direction and length of the channel may be associated with a mapping of the hot areas 118, as described further with respect to FIG. 3, and may be associated with the specifications of the liquid and the semiconductor product 100. The semiconductor product 100 may be associated, in a second step, with an enclosure 108 that is hermetically sealed or that is provided to the semiconductor product 100 in other fixed or removable capping methods appreciated in the semiconductor processing procedures. In a third step, that is optional or that may be performed prior to the second step, a heat sink or cold plate 210 may be associated with the enclosure 108 via a TIM. However, in at least one embodiment, a part of the heatsink or cold plate 210 can be incorporated into the enclosure 108. Therefore, such incorporation may not require a TIM to be included in the system herein.

In one example, the enclosure 108 is provided over the surface 102 of the semiconductor product but covers at least the channel inlet and the channel outlet. This may be a closed loop once liquid to be used for carrying heat is injected into the channel. In at least one embodiment, a chamber or reservoir for the liquid injection may be provided within the collection feature 110. In at least one embodiment, when used in an open loop, there may be an association between the channel outlet 208 and a heat exchanger 256. Further, a pump 258 may be provided to encourage flow or movement 112 associated with the liquid in the open loop. Further, the at least one channel 104 allows flow or movement 112 of the liquid therethrough in either the open or the closed loop. The at least one nozzle or notch 106 allows ejection 114 of the liquid to the surface 102 or to an area 272 above the surface 102 to provide at least part of a cooling for the semiconductor product 100. In at least one embodiment, the cooling may be based in part on heat absorbed to the liquid from a byproduct of a device activity of the semiconductor product 100. The enclosure 108 is to at least partly retain the liquid to support cooling of the semiconductor product. For example, the liquid may be retained within the surface 102 or the area 272 above the surface of the semiconductor product. In a further example, the inner surface 260 of the enclosure 108 allows condensation of vapor 262 from the ejection 114 or allows drops in liquid 264 form from the ejection 114 to deposit thereon. The condensate return 266 and the liquid return 268 collects in the collection feature 110.

Further, the semiconductor product 100 is such that the ejection 114 maintains the liquid in liquid 264 form or supports vaporization of the liquid to a vapor 262 form to the surface 102 or to the area 272 above the surface 102 of the semiconductor product 100 to provide the cooling. Although stated as being above the surface 102 of the semiconductor product 100, the liquid may move by gravity and therefore, the surface 102 may include side surfaces of the semiconductor product 100, at least till a collection feature 110 of the semiconductor product. Therefore, the semiconductor product 100 may be used within a computing device in various alignments, including facing upwards or parallelly upwards relative to a first axis 274A, facing sidewards to the left or the right of the first axis 274A and along the second axis 274B, or facing downwards, which is opposite to the upwards facing direction. The semiconductor product 100 may be such that the flow or movement 112 that is enabled, in part, is by a further cooling of the semiconductor product, in a preheating feature by the system and method herein. For example, the flow or movement 112 may be caused in a closed loop, based in part on a temperature differential in the at least one channel 104. Further, the temperature differential is sufficient to impart a preheat to the liquid so that when it reaches the nozzle or notch 106 it can vaporize to vapor 262 form.

The semiconductor product 100 may be such that the flow or movement 112 may be enabled, in part, by the pump 258 in the open loop where some or all of the liquid is exchanged from the collection feature 110 to a heat exchanger 256. The heat exchanger 256 may be associated with a rack manifold or a server manifold and with primary and secondary cooling loops of a datacenter cooling system in one example. The heat exchanger 256 may be associated with further heat exchanger that is, in turn, associated with a cooling tower. The further heat exchanger and/or the cooling tower form part of an external cooling 270 provided by a primary cooling loop, in one example. In at least one embodiment, therefore, it is possible to use a single heat exchanger 256 for multiple liquid cooling loops which may be associated with different enclosures 108. Therefore, the flow or movement 112 may be supported by an inlet and an outlet, such as the channel inlet and the channel outlet, to allow exchange of the heat absorbed to the liquid with a heat exchanger 256 that is external to the semiconductor product 100.

The semiconductor product 100 may be such that the enclosure 108 may be associated with a heat exchanger 256 to exchange of the heat absorbed to the liquid with the heat exchanger. For example, the pump 258 is illustrated as being used with a heat exchanger 256, it is possible to use the pump only for the closed loop, which is also an active loop, for the flow or movement 112. This may be the case when the specifications or properties of the liquid and of the semiconductor product are such that vacuum is not sufficient to cause the flow or movement 112 via the nozzles and the channels alone. The semiconductor product 100 may be such that the enclosure 108 allows condensation of a vapor 262 form of the liquid or allows redirection of a liquid 264 form of the liquid. The enclosure 108 may allow such redirection via a concave inner shape of the inner surface 260 of the enclosure 108. This is further to enable the liquid to be reused or to exchange heat with a heat exchanger 256 that is external relative to the semiconductor product 100.

In at least one embodiment, FIGS. 2A and 2B also illustrate at least a liquid cooling loop to circulate liquid through a semiconductor product 100 having at least one channel 104 and at least one nozzle or notch 106 formed on a surface 102 thereof. The semiconductor product 100 is associated with an enclosure 108 over the surface 102. The enclosure 108 may also be at least all or part of a side of the semiconductor product 100. The at least one channel 104 allows flow or movement 112 of the liquid therethrough. The at least one nozzle allows ejection 114 of the liquid to the surface 102 or to an area 272 that is above the surface 102 of the semiconductor product 100 to provide at least part of a cooling for the semiconductor product. Further, the liquid cooling loop is a closed loop based on vacuum within a nozzle alone or based on a pump support, or is an open loop based on a heat exchanger supporting the flow or movement 112 of the liquid.

The liquid cooling loop may be such that the ejection 114 maintains the liquid in liquid form or supports vaporization of the liquid to the surface or to the area above the surface to provide the cooling. The liquid cooling loop may be such that the flow or movement 112 is enabled, in part, by a further cooling of the semiconductor product that causes a temperature differential in the at least one channel. The liquid cooling loop may be such that the flow or movement 112 may be enabled, in part, by the pump. The flow or movement 112 may be supported by an inlet and an outlet, such as from the channel inlet and the channel outlet, to allow exchange of the heat absorbed to the liquid with a heat exchanger that is external to the semiconductor product. The liquid cooling loop may be such that the enclosure is associated with a heat exchanger to exchange of the heat absorbed to the liquid with the heat exchanger. Further, the liquid cooling loop may be such that the enclosure allows condensation of a vapor form of the liquid or allows redirection of a liquid form of the liquid. The enclosure is further to enable the liquid to be reused or to exchange heat with a heat exchanger that is external relative to the semiconductor product.

FIG. 3 illustrates aspects 300 of a hot area mapping and liquid cooling loops in embedded jet cooling using channels and at least one nozzle of a semiconductor product, in at least one embodiment. In at least one embodiment, for any semiconductor product 100, a heat distribution map 302 between observed hot areas 312 and observed cold (or dissipation) areas 314 may be generated. The heat distribution map 302 may be generated using in-compute or in-application monitoring or observation of a sample of the semiconductor product 100 performing algorithms designed to stress the semiconductor product or may be during any device activity. In at least one embodiment, the heat distribution map 302 between observed hot areas 312 and observed cold (or dissipation) areas 314 may be generated using simulations of the semiconductor product prior to fabrication. Therefore, the algorithms may be applied to a system under test or to a simulation under test. The observed hot areas 312 may correspond to silicon parts of a semiconductor product, including of III-V semiconductors or compounds used in high-performance optoelectronic devices, heterogeneous, or micro-transfer printed (MTP) chips.

The heat distribution map 302 may be provided to a channel and notch application system 202 that supports a further map 306 between the heat distribution map 302 and a channel map 304. For example, the channel map 304 may include computer-generated linear (or other objective boundary feature) mark-outs of the observed hot areas 312 and the observed cold (or dissipation) areas 314 from the heat distribution map 302. In one example, the intended heat movement 310 part of the heat distribution map 302 may be added based in part on a heat movement intended between the observed hot areas 312 and the observed cold (or dissipation) areas 314.

Further, the channel map 304 may include applied enclosure areas 308. Although illustrated at different boundaries between the components, all the components of a semiconductor product may be subject to a single enclosure 108. The channel map may include suggestive liquid cooling loops from a loop inlet 316, through a channel inlet 206, through the enclosure areas 308, through a channel outlet 208, and through the loop outlet 318. Although only one of each channel inlet and channel outlet are illustrated, it is appreciated that each enclosure area 308 may have such features.

In at least one embodiment, as the number of computing units, per area of a semiconductor product increases, the number of hotspots on the semiconductor increases. Such semiconductor products may require faster and more efficient heat dissipation, which is provided by the embedded jet cooling herein. In addition, the heat generated in a semiconductor product may be due to electrical resistance of different components in the semiconductor product. The heat generated may be such that hotspots or hot areas are formed where the temperature is highest. While a heat removal system that includes heat sinks, liquid cooling, and air cooling may address part of a heat removal from the system, the embedded jet cooling herein is able to efficiently and instant transfer the heat generated all throughout the semiconductor product. This is so that a destination of the heat generated, which is an important role in the overall efficiency of the heat removal process, is suitably able to remove heat instantly from all surfaces of the semiconductor product 100.

In one example, heat removal, from a semiconductor product may be supported via a TIM that is between an outer surface of the enclosure 108 and the heat sink or cold plate 210. The TIM may be placed over an entire outer surface of the enclosure 108 and may be intended to improve thermal contact between the enclosure 108 and the semiconductor product 100. However, the thermal contact may be irregular and non-uniform. The approaches herein focus, in part, on transfer of heat generated from specific components and areas within the semiconductor product, whereas the use of the TIM and the heat removal system may be focused on a generalized cooling using the semiconductor product as a single uniform heat source with minimal in-plane heat spreading. There may be large difference in temperatures between the hot areas and the cold areas of the semiconductor product without the present transfer applied heat spreader material that may be used in addition to the TIM and the heat removal system. However, as explained with respect to at least FIG. 2A, a part of the heatsink or cold plate 210 can be incorporated into the enclosure 108. Therefore, such incorporation may not require a TIM to be included in the system herein.

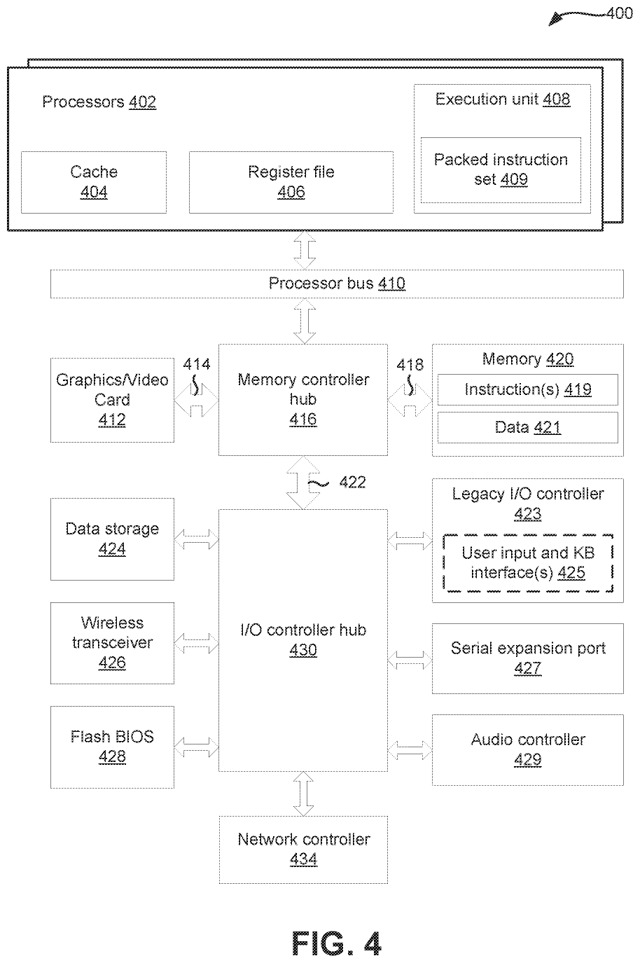

FIG. 4 illustrates computer and processor aspects 400 of embedded jet cooling using channels and at least one nozzle on a semiconductor product, according to at least one embodiment. For example, each of the illustrated processors 402 may include one or more processing or execution units 408 that can perform any or all of the features of the channel and notch application system 202 system. The channel and notch application system 202 may include a human interface to receive one or more of the maps 302-306. However, the channel and notch application system 202 herein can automatically monitor a sample semiconductor product, can automatically generate the heat spreader distribution or the channel map, and can automatically cause the embedded jet cooling features to be performed.

In at least one embodiment, the automation may be performed by one part of the computer and processor aspects 400 performing a stress algorithm for a sample semiconductor product. The automation may be further performed using another part of the computer and processor aspects 400 performing an observation or a monitoring for a semiconductor product performing the stress algorithm, to generate a heat distribution map for the semiconductor product. The automation is still further performed by a mapping part of the computer and processor aspects 400 that generates the heat spreader distribution or the channel map, from the heat distribution map.

The processing or execution units 408 may include multiple circuits to support the automation described herein and the interface described herein. In at least one embodiment, the processors 402 may include CPUs, GPUs, DPUs that may be associated with a multi-tenant environment to perform one or more of the transfer application features described herein. Further, the GPUs may be distinctly in distinct graphics/video cards 412, relative to a DPU (represented by a network controller 434) and a CPU represented by the processors 402 illustrated in FIG. 4. Therefore, even though described in the singular, the graphics/video card 412 may include multiple cards and may include multiple GPUs on each card.

The computer and processor aspects 400 may be performed by one or more processors 402 that include a system-on-a-chip (SOC) or some combination thereof formed with a processor that may include execution units to execute an instruction, according to at least one embodiment. In at least one embodiment, the computer and processor aspects 400 may include, without limitation, a component, such as a processor 402 to employ execution units 408 including logic to perform algorithms for process data, in accordance with present disclosure, such as in embodiment described herein. In at least one embodiment, the computer and processor aspects 400 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, the computer and processor aspects 400 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, optical transmitters, optical receivers, optical transceivers, or any other system that may perform one or more instructions in accordance with at least one embodiment.

In at least one embodiment, the computer and processor aspects 400 may include, without limitation, a processor 402 that may include, without limitation, one or more execution units 408 to perform aspects according to techniques described with respect to at least one or more of FIGS. 1-3 and 5-7 herein. In at least one embodiment, the computer and processor aspects 400 is a single processor desktop or server system, but in another embodiment, the computer and processor aspects 400 may be a multiprocessor system.

In at least one embodiment, the processor 402 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, a processor 402 may be coupled to a processor bus 410 that may transmit data signals between processors 402 and other components in computer and processor aspects 400.

In at least one embodiment, a processor 402 may include, without limitation, a Level 1 (“L1”) internal cache memory (“cache”) 404. In at least one embodiment, a processor 402 may have a single internal cache or multiple levels of internal cache. In at least one embodiment, cache memory may reside external to a processor 402. Other embodiments may also include a combination of both internal and external caches depending on particular implementation and needs. In at least one embodiment, a register file 406 may store different types of data in various registers including, without limitation, integer registers, floating point registers, status registers, and an instruction pointer register.

In at least one embodiment, an execution unit 408, including, without limitation, logic to perform integer and floating point operations, also resides in a processor 402. In at least one embodiment, a processor 402 may also include a microcode (“ucode”) read only memory (“ROM”) that stores microcode for certain macro instructions. In at least one embodiment, an execution unit 408 may include logic to handle a packed instruction set 409.

In at least one embodiment, by including a packed instruction set 409 in an instruction set of a general-purpose processor, along with associated circuitry to execute instructions, operations used by many multimedia applications may be performed using packed data in a processor 402. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, an execution unit 408 may also be used in microcontrollers, embedded processors, graphics devices, DSPs, and other types of logic circuits. In at least one embodiment, the computer and processor aspects 400 may include, without limitation, a memory 420. In at least one embodiment, a memory 420 may be a Dynamic Random Access Memory (“DRAM”) device, a Static Random Access Memory (“SRAM”) device, a flash memory device, or another memory device. In at least one embodiment, a memory 420 may store instruction(s) 419 and/or data 421 represented by data signals that may be executed by a processor 402.

In at least one embodiment, a system logic chip may be coupled to a processor bus 410 and a memory 420. In at least one embodiment, a system logic chip may include, without limitation, a memory controller hub (“MCH”) 416, and processors 402 may communicate with MCH 416 via processor bus 410. In at least one embodiment, an MCH 416 may provide a high bandwidth memory path 418 to a memory 420 for instruction and data storage and for storage of graphics commands, data, and textures. In at least one embodiment, an MCH 416 may direct data signals between a processor 402, a memory 420, and other components in the computer and processor aspects 400 and to bridge data signals between a processor bus 410, a memory 420, and a system I/O interface 422. In at least one embodiment, a system logic chip may provide a graphics port for coupling to a graphics controller. In at least one embodiment, an MCH 416 may be coupled to a memory 420 through a high bandwidth memory path 418 and a graphics/video card 412 may be coupled to an MCH 416 through an Accelerated Graphics Port (“AGP”) interconnect 414. In at least one embodiment, the graphics/video card 412 may be coupled to one or more of the processors 402 via a PCIe interconnect standard. Similarly, a network controller 424 may also be coupled to one or more of the processors 402 via a PCIe interconnect standard.

In at least one embodiment, the computer and processor aspects 400 may use a system I/O interface 422 as a proprietary hub interface bus to couple an MCH 416 to an I/O controller hub (“ICH”) 430. In at least one embodiment, an ICH 430 may provide direct connections to some I/O devices via a local I/O bus. In at least one embodiment, a local I/O bus may include, without limitation, a high-speed I/O bus for connecting peripherals to a memory 420, a chipset, and processors 402. Examples may include, without limitation, an audio controller 429, a firmware hub (“flash BIOS”) 428, a wireless transceiver 426, a data storage 424, a legacy I/O controller 423 containing user input and keyboard interface(s) 425, a serial expansion port 427, such as a Universal Serial Bus (“USB”) port, and a network controller 434. In at least one embodiment, data storage 424 may comprise a hard disk drive, a floppy disk drive, a CD-ROM device, a flash memory device, or other mass storage device.

In at least one embodiment, FIG. 4 illustrates computer and processor aspects 400, which includes interconnected hardware devices or “chips”, whereas in other embodiments, FIG. 4 may illustrate an exemplary SoC. In at least one embodiment, devices illustrated in FIG. 4 may be interconnected with proprietary interconnects, standardized interconnects (e.g., PCIe) or some combination thereof. In at least one embodiment, one or more components of the computer and processor aspects 400 that are interconnected using compute express link (CXL) interconnects.

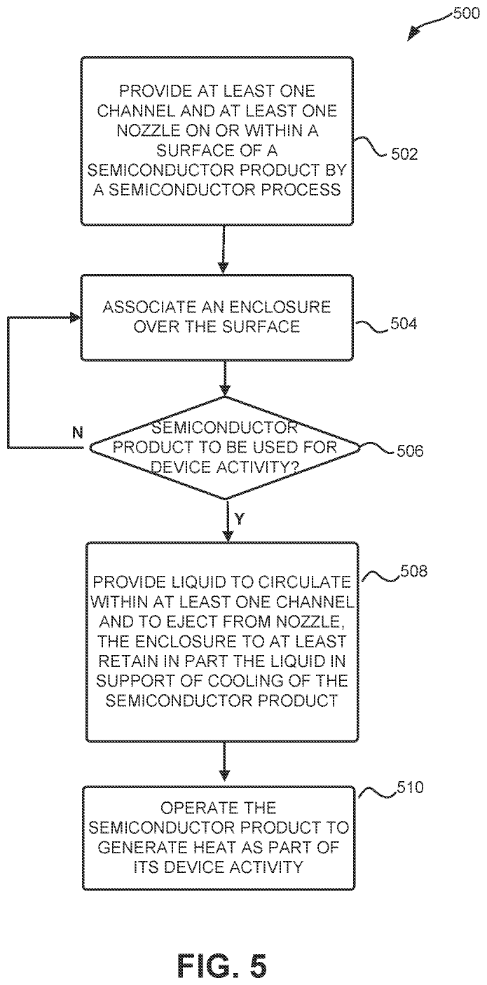

FIG. 5 illustrates a process flow or method 500 for embedded jet cooling using channels and at least one nozzle of a semiconductor product, according to at least one embodiment. The method 500 may include providing 502 at least one channel and at least one nozzle of a surface of a semiconductor product by a semiconductor process that may include one or more of micro-milling, etching, deposition, lithography, embossing processes, and laser ablation processing. The method 500 may include associating 504 an enclosure over the surface of the semiconductor product. The method may include verifying 506 that the semiconductor device is ready for use device activity, such as for a computer process or to be powered within a computing device.

The method 500 may include providing 508 liquid to circulate within the at least one channel and to eject from the nozzle. For example, this may include injecting liquid for closed loop cooling or may include associating the enclosure with a heat exchanger for open loop cooling. In at least one embodiment, it is possible to inject the liquid to a chamber or reservoir for that may be associated within a collection feature of the enclosure. The enclosure is further to at least retain in part the liquid to support cooling of the semiconductor product. For example, the liquid may be retained within the surface or an area above the surface in support of the cooling of the semiconductor product. The method 500 may include operating 510 the semiconductor product to generate heat as part of the device activity, where the heat is removed by being absorbed to the liquid from a byproduct of the device activity, and where the enclosure is to at least retain partly the liquid to support cooling of the semiconductor product. For example, the liquid may be retained within the surface or the area above the surface of the semiconductor product.

In at least one embodiment, the method 500 may include a further step or a sub-step of maintaining, by the ejection of the liquid, a liquid form for the liquid. Still further, such a step or sub-step may include supporting, by the ejection of the liquid, a vaporization of the liquid to the surface or to the area above the surface to provide the cooling. The method 500 may include a further step or a sub-step of enabling the flow, in part, by a further cooling of the semiconductor product that causes a temperature differential in the at least one channel. This step or sub-step may be provided by ensuring a mapping to have the channel extending through a section of the semiconductor product that allows for preheating of the liquid, in one example. The method 500 may include a further step or a sub-step of enabling the flow, in part, by a pump. The flow may be supported by an inlet and an outlet to allow exchange of the heat absorbed to the liquid with a heat exchanger that is external to the semiconductor product.

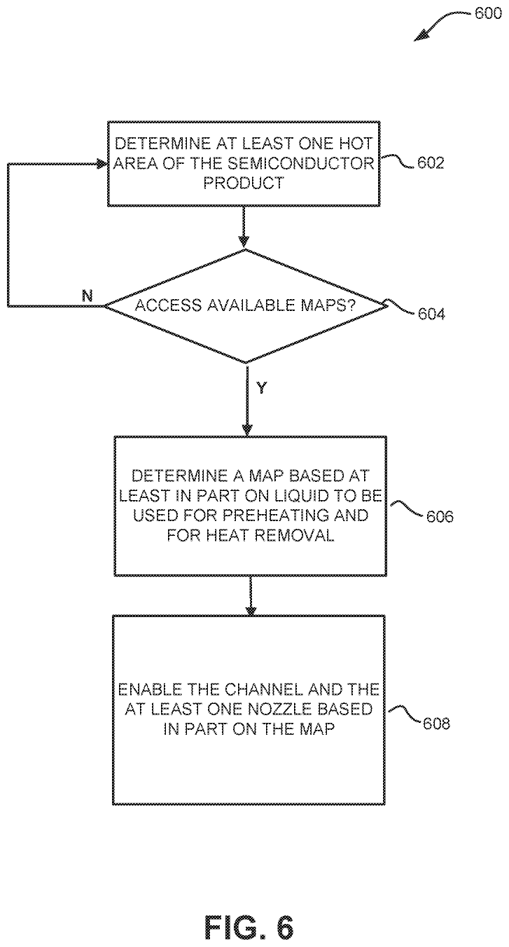

FIG. 6 illustrates yet another process flow or method 600 for embedded jet cooling using channels and at least one nozzle of a semiconductor product, according to at least one embodiment. The method 600 of FIG. 6 may be used with the method 500 of FIG. 5. For example, the method 600 includes determining 602 at least one hot area of a semiconductor product. This may be in part as described by the features in FIG. 3. The method 600 may include accessing 604 available maps between hot areas and channels maps. The method 600 includes determining 606 a map, from the accessed maps, based at least in part on liquid to be preheated and to be used to remove heat from the semiconductor product by the embedded jet cooling herein. For example, a map may be selected according to specifications of the liquid that will enable vaporization of the liquid within a length of a channel (with respect to a location of a nozzle, for instance). Further, the specifications of the liquid may be associated with the amount of heat removed using preheating in a first action and by vaporization or spray of the liquid into the enclosure in a second action. Based in part on such information in the map selected, the method 600 herein is used to enable 608 the channel and the nozzle in a semiconductor device by semiconductor and other processes as detailed in FIGS. 1-5.

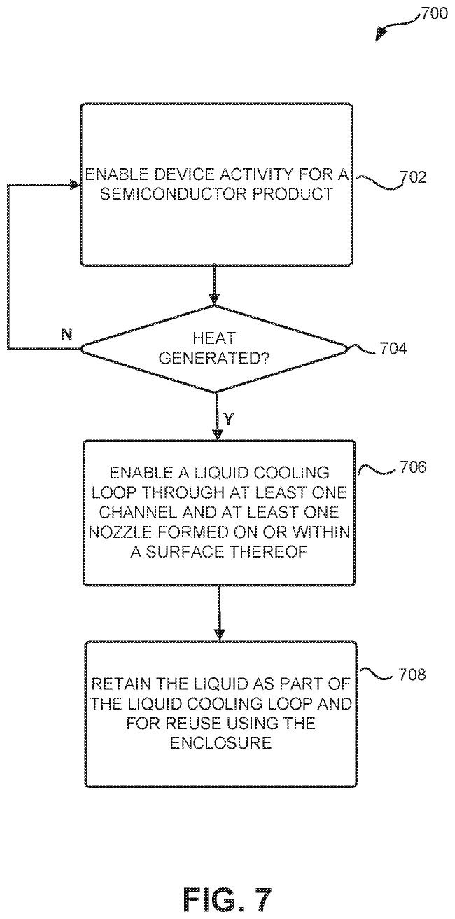

FIG. 7 illustrates a further process flow or method 700 for operating a semiconductor product having embedded jet cooling using channels and at least one nozzle of the semiconductor product, according to at least one embodiment. The method 700 of FIG. 7 may be used with the method 500 of FIG. 5 or the method 600 of FIG. 6. For example, the method 700 is for a semiconductor product having at least one channel and at least one nozzle formed on a surface thereof and that is associated with an enclosure that is over the surface. The method 700 may include enabling 702 device activity for the semiconductor product.

As the semiconductor product having the embedded jet cooling is self-regulating, the method 700 may include verifying 704 that heat is generated as part of the device activity for a semiconductor product. Such verification 704 may be useful for engaging aspects of the open loop to cause cooling in the semiconductor product. For example, a pump may be engaged to move the liquid at a rate to address the heat generated. Such verification 704 may be useful also in the closed loop as the closed loop is optimized for a determined level of heat generated according to the specifications of the liquid used, the channel lengths, the device activity that stresses the semiconductor product. The method 700 includes enabling 706 a liquid cooling loop for the semiconductor product, based in part on heat absorbed to the liquid from a byproduct of the device activity. The liquid cooling loop is to circulate liquid through the at least one channel and the at least one nozzle to allow ejection of the liquid to the surface or to an area above the surface to provide at least part of a cooling for the semiconductor product. The circulation of liquid may be based in part on the heat absorbed to the liquid, in at least one embodiment. The method 700 may include the use of the enclosure to at least retain 708 partly the liquid to support cooling of the semiconductor product. For example, the liquid may be retained to within the liquid cooling loop for reuse within enclosure. This may include retaining, by the enclosure, the liquid within the surface or the area above the surface of the semiconductor product.

In at least one embodiment, the method 700 may include a step or sub-step for maintaining, by the ejection of the liquid, a liquid form for the liquid. The method 700 may include a step or sub-step for supporting, by the ejection of the liquid, a vaporization of the liquid to the surface or to the area above the surface to provide the cooling. The method 700 may include a step or sub-step for enabling the flow, in part, by a further cooling of the semiconductor product that causes a temperature differential in the at least one channel. This may reflect preheating of the liquid that absorbs some part of the heat in a first action of operation, followed by absorbing more heat as part of the ejection from the nozzle, as a second action of operation. The method 700 may include a step or sub-step for enabling the flow, in part, by a pump. The flow may be supported by an inlet and an outlet to allow exchange of the heat absorbed to the liquid with a heat exchanger that is external to the semiconductor product.

In the following description, numerous specific details are set forth to provide a more thorough understanding of at least one embodiment. However, it will be apparent to one skilled in the art that the inventive concepts may be practiced without one or more of these specific details.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A semiconductor product comprising at least one channel and at least one nozzle formed on or within a surface thereof and associated with an enclosure over the surface, the at least one channel to allow flow of a liquid therethrough, the at least one nozzle to allow ejection of the liquid to the surface or to an area above the surface to provide at least part of a cooling for the semiconductor product, based in part on heat absorbed to the liquid, and the enclosure to at least retain partly the liquid in support of the cooling of the semiconductor product.

2. The semiconductor product of claim 1, wherein the ejection maintains the liquid in liquid form or supports vaporization of the liquid to the surface or to the area above the surface to provide the cooling.

3. The semiconductor product of claim 1, wherein the flow is enabled, in part, by a further cooling of the semiconductor product that causes a temperature differential in the at least one channel.

4. The semiconductor product of claim 1, wherein the flow is enabled, in part, by a pump, and wherein the flow is supported by an inlet and an outlet to allow exchange of the heat absorbed to the liquid with a heat exchanger that is external to the semiconductor product.

5. The semiconductor product of claim 1, wherein the enclosure is associated with a heat exchanger to exchange of the heat absorbed to the liquid with the heat exchanger.

6. The semiconductor product of claim 1, wherein the enclosure allows condensation of a vapor form of the liquid or allows redirection of a liquid form of the liquid, the enclosure further to enable the liquid to be reused or to exchange heat with a heat exchanger that is external relative to the semiconductor product.

7. The semiconductor product of claim 1, wherein the heat absorbed to the liquid is based in part on a byproduct of device activity within the semiconductor product.

8. A liquid cooling loop to circulate liquid through a semiconductor product comprising at least one channel and at least one nozzle formed on or within a surface thereof and associated with an enclosure over the surface, the at least one channel to allow flow of the liquid therethrough, the at least one nozzle to allow ejection of the liquid to the surface or to an area above the surface to provide at least part of a cooling for the semiconductor product, based in part on heat absorbed to the liquid, and the enclosure to at least partly retain the liquid in support of the cooling of the semiconductor product, wherein the liquid cooling loop is a closed loop or is an open loop with a heat exchanger.

9. The liquid cooling loop of claim 8, wherein the ejection maintains the liquid in liquid form or supports vaporization of the liquid to the surface or to the area above the surface to provide the cooling.

10. The liquid cooling loop of claim 8, wherein the flow is enabled, in part, by a further cooling of the semiconductor product that causes a temperature differential in the at least one channel.

11. The liquid cooling loop of claim 8, wherein the flow is enabled, in part, by a pump, and wherein the flow is supported by an inlet and an outlet to allow exchange of the heat absorbed to the liquid with a heat exchanger that is external to the semiconductor product.

12. The liquid cooling loop of claim 8, wherein the enclosure is associated with a heat exchanger to exchange of the heat absorbed to the liquid with the heat exchanger.

13. The liquid cooling loop of claim 8, wherein the enclosure allows condensation of a vapor form of the liquid or allows redirection of a liquid form of the liquid, the enclosure further to enable the liquid to be reused or to exchange heat with a heat exchanger that is external relative to the semiconductor product.

14. The liquid cooling loop of claim 8, wherein the heat absorbed to the liquid is based in part on a byproduct of device activity within the semiconductor product.

15. A method comprising:
providing at least one channel and at least one nozzle on or within a surface of a semiconductor product by a semiconductor process;
associating an enclosure over the surface; and
providing liquid to circulate within the at least one channel and to eject from the nozzle, wherein the enclosure is to at least retain in part the liquid in support of cooling to be provided to the semiconductor product.

16. The method of claim 15, further comprising:
maintaining, by the ejection of the liquid, a liquid form for the liquid; or
supporting, by the ejection of the liquid, a vaporization of the liquid to the surface or to the area above the surface to provide the cooling.

17. The method of claim 15, further comprising:
enabling the flow, in part, by a further cooling of the semiconductor product that causes a temperature differential in the at least one channel.

18. The method of claim 15, further comprising:
enabling the flow, in part, by a pump, wherein the flow is supported by an inlet and an outlet to allow exchange of heat absorbed to the liquid with a heat exchanger that is external to the semiconductor product.

19. The method of claim 15, further comprising:
enabling the flow, in part, by heat generated from device activity in the semiconductor product.

20. A method comprising:
enabling device activity for a semiconductor product, the semiconductor product comprising at least one channel and at least one nozzle formed on or within a surface thereof and associated with an enclosure over the surface; and
enabling a liquid cooling loop for the semiconductor product, based in part on heat absorbed to the liquid, the liquid cooling loop to circulate liquid through the at least one channel and the at least one nozzle to allow ejection of the liquid to the surface or to an area above the surface to provide at least part of a cooling of the semiconductor product, based in part on the heat absorbed to the liquid, wherein the enclosure is to at least partly retain the liquid in support of the cooling of the semiconductor product.

21. The method of claim 20, further comprising:
maintaining, by the ejection of the liquid, a liquid form for the liquid; or
supporting, by the ejection of the liquid, a vaporization of the liquid to the surface or to the area above the surface to provide the cooling.

22. The method of claim 20, further comprising:
enabling the flow, in part, by a further cooling of the semiconductor product that causes a temperature differential in the at least one channel.

23. The method of claim 20, further comprising:
enabling the flow, in part, by a pump, wherein the flow is supported by an inlet and an outlet to allow exchange of the heat absorbed to the liquid with a heat exchanger that is external to the semiconductor product.

24. The method of claim 20, further comprising:
enabling the flow, in part, by the heat generated from device activity in the semiconductor product.
